(19) United States
(12) Patent Application Publication
(10) Pub. No.: US 2009/0092470 A1
(43) Pub. Date: Apr. 9, 2009

(54) END EFFECTOR WITH SENSING CAPABILITIES

(76) Inventor: Anthony C. Bonora, Fremont, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 12/244,693

(22) Filed: Oct. 2, 2008

Related U.S. Application Data
(60) Provisional application No. 60/977,357, filed on Oct. 3, 2007.

(51) Int. Cl. H01L 21/683

(52) U.S. Cl. 414/226.01; 414/222.02

(57) ABSTRACT

In one embodiment, an end effector having a first arm extending from an end effector support body, and a second arm extending from the end effector support body is provided. The first arm and the second arm have support extensions for supporting a peripheral region of a substrate, wherein the second arm and the first arm include sensors integrated thereon. The sensors are located at a distal end of the first and the second arms past the corresponding support extensions. The sensors are configured to indicate whether support arms for a container are within the travel path of the end effector in one embodiment. The end effector may be integrated into a system for transporting substrates.

### CLAIM OF PRIORITY

The present application claims priority under 35 U.S.C. § 119(e) from U.S. Provisional Patent Application No. 60/977,357, filed Oct. 3, 2007, which is incorporated by reference in its entirety for all purposes.

### BACKGROUND

The manufacturing of semiconductor components relies on automation for yield and cleanliness purposes. The transfer of substrates to and from front opening unified pods (FOUPs) and process tools is one area where losses can take place in the form of damage to the substrates or damage to the end effectors moving the substrates. Current systems are unable to determine the relative location of the substrates to be transferred and the end effector providing the transfer mechanism. Thus, there is no mechanism to determine whether the end effector has the proper clearance to insert or remove substrates from the carrier or front opening unified pod. Consequently, the substrates can be scratched, damaged, or destroyed by the end effector depending on the severity of any collision between the end effector and the substrate. As the end effectors move into the carriers at rapid velocities and high acceleration, the potential for damage is great for instances where there is misalignment between the end effector and the substrate. The clearance for the end effector is typically +/−4 millimeters, which does not leave much room for error. For an edge gripping end effector the clearance can be reduced to +/−3.5 millimeters. This clearance must account for substrate position errors, substrate flatness, and other mechanical tolerances. Additionally, when one substrate is destroyed, the damage can be translated to all the substrates in the carrier.

Accordingly, improvements are needed in order to detect any possible misalignment and prevent damage to the substrates.

### SUMMARY

Broadly speaking, the present invention fills these needs by providing an architecture for a transport system within a fabrication facility. It should be appreciated that the present invention can be implemented in numerous ways, including as a method, a system, or an apparatus. Several inventive embodiments of the present invention are described below.

In one embodiment, an end effector having a first arm extending from an end effector support body, and a second arm extending from the end effector support body is provided. The first arm and the second arm have support extensions for supporting a peripheral region of a substrate, wherein the second arm and the first arm include sensors integrated thereon. The sensors are located at a distal end of the first and the second arms past the corresponding support extensions. The sensors are configured to indicate whether support arms for a container are within the travel path of the end effector in one embodiment. The end effector may be integrated into a system for transporting substrates.

Other aspects and advantages of the invention will become apparent from the following detailed description, taken in conjunction with the accompanying drawings, illustrating by way of example the principles of the invention.

### BRIEF DESCRIPTION OF THE DRAWINGS

Aspects of the present invention will become apparent from the following detailed description, taken in conjunction with the accompanying drawings, illustrating by way of example the principles of the invention.

FIG. 1A is a simplified schematic diagram illustrating a relationship between an end effector and support chuck in accordance with one embodiment of the invention.

FIG. 1B illustrates an alternative embodiment of the end effector shown in operation with a wafer chuck in accordance with one embodiment of the invention.

FIG. 2 is a simplified schematic diagram illustrating an end effector with pre-sensing capabilities in accordance with one embodiment of the invention.

FIG. 3 is a simplified schematic diagram illustrating a slide body extension on an end effector wherein a sensor is disposed on an extension affixed to slide body in accordance with one embodiment of the invention.

FIG. 4 is a simplified schematic diagram illustrating a side elevation view of an end effector having image sensing capabilities for moving a substrate in accordance with one embodiment of the invention.

FIG. 5 is a simplified schematic diagram of an end effector having roll control in accordance with one embodiment of the invention.

FIG. 6 is a simplified schematic diagram of an end effector having retractable support extensions in accordance with one embodiment of the invention.

### DETAILED DESCRIPTION

An invention is described for an end effector and a system for handling semiconductor substrates involved in semiconductor manufacturing operations. It will be obvious, however, to one skilled in the art, that the present invention may be practiced without some or all of these specific details. In other instances, well known process operations have not been described in detail in order not to unnecessarily obscure the present invention.

The embodiments described herein provide for an end effector having sensing capabilities in order to detect a position of the end effector relative to substrates within a support container. In one embodiment the end effector is an edge grip end effector. In another embodiment, the end effector supports a bottom surface of the substrate. The area on the bottom surface that the end effector may be located on an outer periphery of the substrate. In this embodiment, the end effector may be utilized with a support container having a support structure with support extensions providing support for the substrate inside the outer periphery of the bottom surface of the substrate. The sensor is integrated into arms extending from a support body of the end effector. Thus, the end effector may be utilized to scan the substrate positions within a support container, as the end effector arms are disposed outside a periphery of the substrates within the container and inside the container walls. The support pads supporting the substrate on the end effector may also include sensors configured to detect the presence of the substrate in order to confirm capturing of the substrate by the end effector in one embodiment.

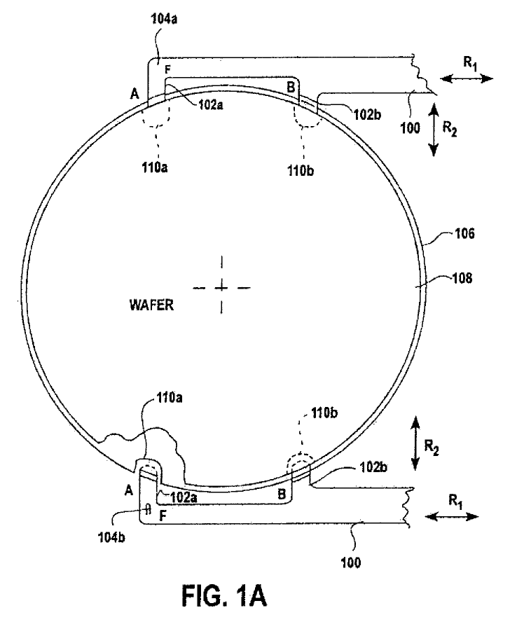

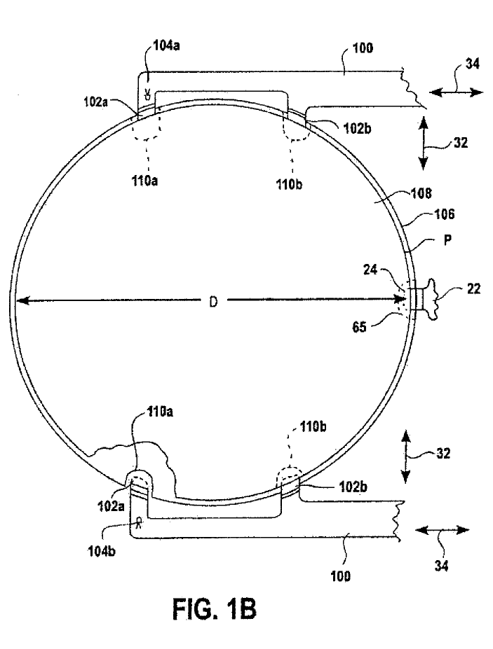

FIG. 1A is a simplified schematic diagram illustrating a relationship between an end effector and support chuck in accordance with one embodiment of the invention. End effector 100 includes a pair of arms with protruding support grips 102a and 102b. Sensors 104a and 104b are also illustrated as being incorporated or integrated into end effector 100. Support chuck 106 supports wafer 108. In one embodiment chuck 106 includes relief indentations 110a and 110b to accommodate the vertical movement of end effector 100, and more particularly, the vertical movement of support grips 102a and 102b. Relief indentations 110a and 110b enable the end effector support grips 102a and 102b to clear the support chuck so that the end effector may drop down to transfer a wafer to the top of support chuck 106. In one embodiment, relief indentations 110a and 110b proceed all the way to a bottom surface of chuck 106 for access to and from wafer 108 by end effector 100.

In another embodiment, the chuck may have a slot defined around a perimeter, as well as relief indentations, to enable the end effector to be withdrawn horizontally, after dropping vertically, once the wafer is placed on chuck 106. Of course, the perimeter slot also enables the end effector to obtain the wafer in this embodiment. It should be appreciated that support chuck 106 may be used for any suitable processing machine or metrology apparatus utilized in semiconductor manufacturing, flat panel display manufacturing, or other suitable processes. In one embodiment, sensors 104a and 104b may be on an extension to the front of the end effector grips in order to function to guide the insertion of wafer 108 into a container as will be described in more detail below.

FIG. 1B illustrates an alternative embodiment of the end effector shown in operation with a wafer chuck in accordance with one embodiment of the invention. In particular, the wafer chuck 106 includes two pairs of relief channels 110a and 110b. Each relief channel is aligned such that the end effector 100 may lower the wafer 108 onto the chuck 106 and there is no contact between the wafer chuck 106 and the end effector. Once the wafer 108 is seated on the chuck 106, the end effector arms may move laterally away from the chuck 106 in the direction 32 and then retract from the chuck 106 in the direction 34. In one embodiment, chuck 106 also includes indentation 65 to accommodate support 22 and support grip 24. One skilled in the art will appreciate that chuck 106 may include any number of relief indentations configured to accommodate the support extensions of the end effector. In addition, where chuck 106 includes a slot defined around a perimeter of the chuck, each of the support extensions can be within the same plane so that a single slot provides access to all the support extensions.

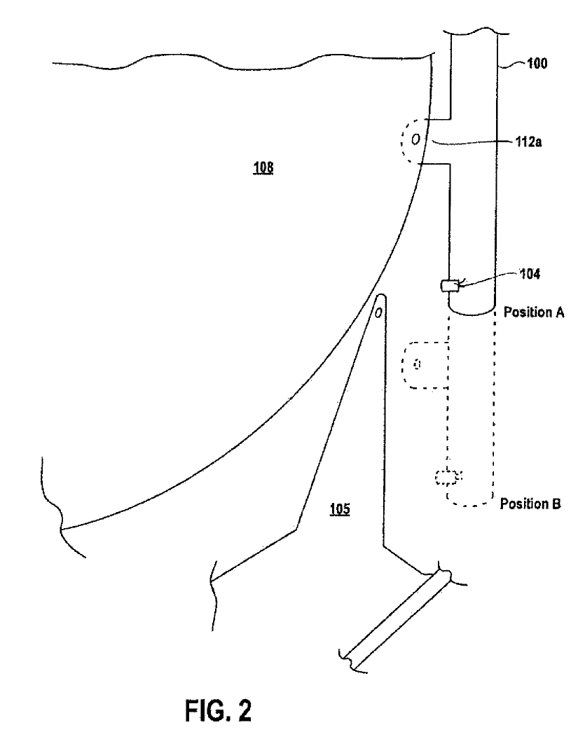

FIG. 2 is a simplified schematic diagram illustrating an end effector with pre-sensing capabilities in accordance with one embodiment of the invention. End effector 100 includes a support extension 112a on top of which rests wafer 108. End effector 100 also includes an extension arm extending past support arm 112a, in which the extension includes sensor 104. Sensor 104 may be used to guide a wafer into a container such as the container described in relation to U.S. patent application Ser. No. 11/483,366, which is incorporated herein for all purposes. In one embodiment, sensor 104 may be positioned along the same plane of travel as wafer 108. In another embodiment, sensor 104 is positioned so as to follow the same plane of the end effector arms. As discussed below, sensor 104 can be positioned above or below the plane of travel of wafer 108 depending on the application. If sensor 104 detects an obstacle such as the wafer 108 being too low or too high relative to a support arm 150 in the container, the sensor can trigger an emergency stop through a computing device in communication with both the end effector 100 and the sensor 104. The computing device may also adjust the relative positioning of the end effector and the wafer/container so as not to cause any damage or collisions. In one embodiment, the computing device may record the position data from an initial scan to map the wafers in the container. One skilled in the art will appreciate that a personal computer having software configured to record the data and/or adjust the position of the end effector in response to the sensed signals provides the structure to achieve this functionality.

It should be appreciated that sensor 104 of FIG. 2 may be a break-the-beam sensor, an image capture device, or other suitable sensor commercially available. Where sensor 104 captures image data, the image data may be manipulated through a computing device in communication with a sensor in order to provide further information such as location, tilting of the wafer, etc. In another embodiment, multiple sensors positioned on end effector 100 may be incorporated. For example, a sensor array may be used where the sensors are placed above and below the plane of the wafer on each arm of end effector 100. In this embodiment, the sensor arrays may be utilized to map the tilt or deflections of a wafer in a container. Other spatial features that may be sensed or mapped include Z-position, Y-position, and roll. In yet another embodiment, the wafer supports of the container (support arm 150) illustrated in FIG. 2 may be included in an open structure or nesting rather than a closed container. For example, the wafer supports can be affixed to a metal support extending from a base support in the open structure. In addition, the open structure may be utilized as a shipping container where the open structure is either placed into a shipping container or an enclosure is placed around the open structure.

In FIG. 2, the arms of end effector 100 are illustrated in two positions (position A and position B). In one embodiment, where the end effector is removing the wafer from the container, sensor 104 can be used to detect whether the end effector arms are correctly positioned so as not to not to collide with support arm 150. For example, through a break the beam sensor, a beam from sensor 104 will be broken by support arm 150 if end effector 100 is not correctly positioned. The sensor affixed to a corresponding arm of end effector 100 receives the beam or lack of one. As mentioned above, a computing device receives the signals from the sensors and can terminate or adjust the movement of end effector 10 to avoid a collision.

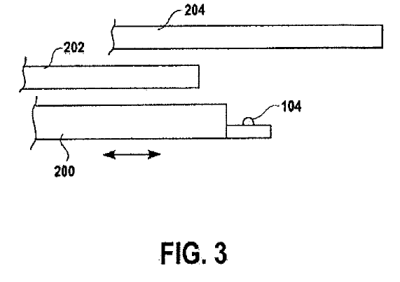

FIG. 3 is a simplified schematic diagram illustrating a slide body extension on an end effector wherein a sensor is disposed on an extension affixed to slide body in accordance with one embodiment of the invention. In one embodiment, slide body 200, is the slide body of SPARTAN WAFER ENGINE of the assignee. In this embodiment, the sensor or image capture device 104 may be used to view a selected portion or area of the wafer in order to provide detailed information as to the positioning and angular orientation of the wafer. In another embodiment, the image capture device may capture markings on the surface of wafer 204. For example, as wafer one 202 is being moved through an end effector, the sensing device may capture data for wafer two 204, which is to be removed next. Of course, the image capture device may capture markings on either wafer one or wafer two and this captured data may be used to gather information as explained in U.S. patent application Ser. No. 12/143,196, which is incorporated herein by reference for all purposes. One skilled in the art will appreciate that the information captured through the image capture device or sensor may be used by a processing tool to which the wafer will subsequently be delivered.

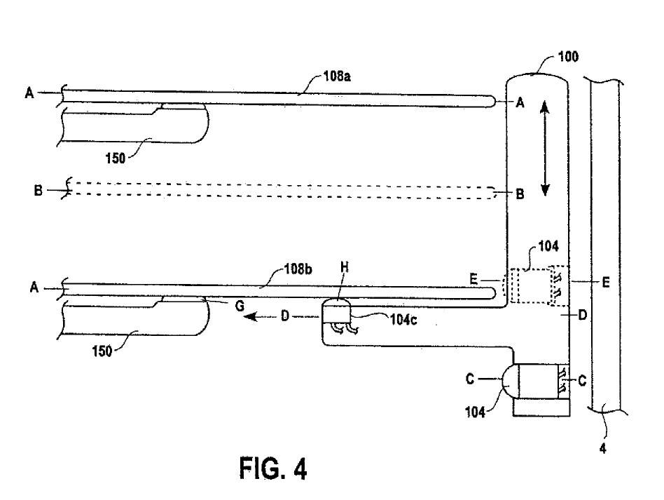

FIG. 4 is a simplified schematic diagram illustrating a side elevation view of an end effector having image sensing capabilities for moving a substrate in accordance with one embodiment of the invention. Wafer 108a and wafer 108b are supported on a wafer support of a container. End effector 100 includes sensor 104 positioned to detect the support structure features of the container. End effector 100 may include additional sensors that may be used to map a wafer's position within a container or on a process chuck or even detect the presence of a wafer, such as sensor 104c. These additional sensors may also provide a line of sight for the wafer plane or for evaluating the wafer support positions, among other information. As illustrated in FIG. 4, the different planes are depicted as follows: A-A is the wafer plane, B-B is the plane of the wafer during extraction/insertion. C-C and E-E are sensing planes, and D-D is the plane of the support arm of the end effector. Contact points H and G of the end effector and the wafer support, respectively, are configured to support the wafer without adding contamination or damaging the wafer. In one embodiment, contact points G and H are integrated with the corresponding end effector or wafer support surface. Additionally, contact points G and H may contact the wafer surface within a defined circumferential zone for a uniform practice of where the wafer is contacted.

In one embodiment, the material of composition for contact points G and H of FIG. 4 is an elastomeric material having a high coefficient of friction. For high temperature applications, the contact points may be composed of quartz or some other suitable material compatible with the heat that will not shed particles or contaminate the wafer. In another embodiment, sensors, such as sensor 104c may be integrated into the contact points in order to sense acquisition of the wafer as an alternative to monitoring vacuum conditions. For example, sensor 104c may include the capability of sensing conductivity, capacitance, weight, vacuum level or some other suitable variable indicative of the wafer being placed upon the contact points so that the end effector has control of the movement of the wafer. In one embodiment, sensor 104c is in communication with the computing device receiving signals from sensors 104. The computing device processes the signals from sensor 104c in order to determine acquisition of a wafer by the end effector through the means described above. It should be appreciated that the end effector of FIG. 4 may be utilized with the chuck of FIG. 1.

Still referring to FIG. 4, the design of the container and end effector in this exemplary embodiment will now be described in more detail. A gap exists between container wall 4 and the outer edge of wafers 108 supported within the container. The arms of end effector 100 are configured to extend into this gap in order to transport the wafers. Accordingly, the end effector 100 contacts the wafer past a centerline of the wafer towards a backside of the container. In one embodiment, end effector 100 includes a support on the opposing side of the centerline, i.e., towards a front region of the container as illustrated in FIG. 1B. End effector 100 may have additional support grips also. However, multiple support grips are optional. Thus, as end effector 100 contacts the wafer to be transported from the container in this configuration, the end effector supports an outer periphery of the wafer between support arms 150 and container wall 4. Traveling along a support path connecting corresponding support grips of the end effector from a center region of the wafer to the container shell, the following structures are disposed: the support arm of the container, an outer periphery of the substrate, a support grip of the end effector, a gap, and then container wall 4. In one embodiment, sensors 104 are integrated into an end effector support body from which the support arms extend. Sensors 104 can be positioned to detect a possible collision between the end effector arms and a body in the plane of travel of the end effector arms.

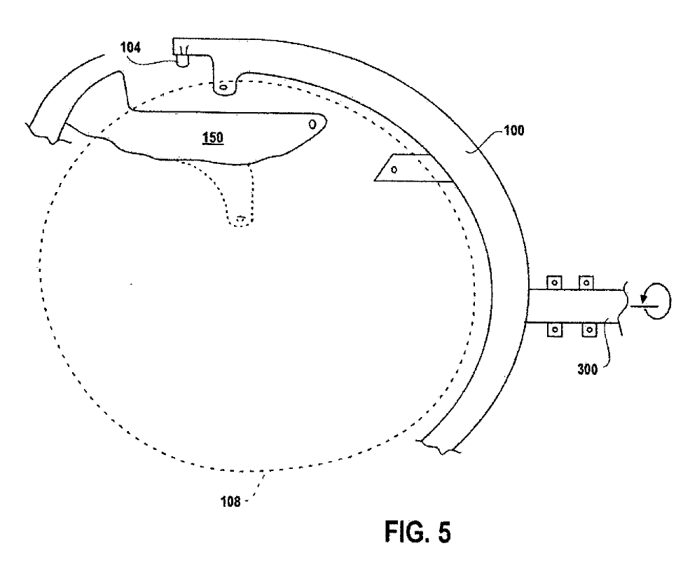

FIG. 5 is a simplified schematic diagram of an end effector having roll control in accordance with one embodiment of the invention. End effector 100, which has sensor 104 integrated thereon (and may have an opposing sensor also) is supported through rotatable arm 300. Rotatable arm 300 may be capable of rotating to adjust the roll of the end effector through known mechanical means, such as the inclusion of ball bearings with arm 300. Thus, if one of the sensors described herein indicates that the roll of the wafer is in need of being adjusted, the end effector can translate to adjust the roll through the mechanism of FIG. 5. Alternatively, in response to sensing a condition where the roll needs to be adjusted, the kinematic pins supporting a FOUP, or any other container holding the wafers, may be adjusted to compensate for the roll of the wafer. It should be appreciated that as wafers in the semiconductor industry transition to 450 mm and the pitch of the containers supporting these wafers is at about 10 mm, the control of the roll will enable efficient and safe handling of the wafers that will avoid incurring any damage to the wafers. Furthermore, the ability to control roll will also benefit placement of the wafers into semiconductor manufacturing tools through slot valves or other suitable orifices during the manufacturing process.

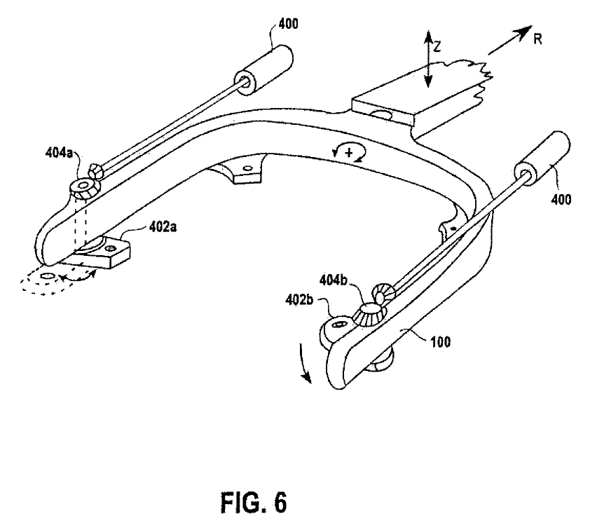

FIG. 6 is a simplified schematic diagram of an end effector having retractable support extensions in accordance with one embodiment of the invention. End effector 100 includes the ability to translate vertically (Z movement), control roll as discussed with regard to FIG. 5, and planar movement as illustrated by R. In addition, end effector 100 includes retractable support extensions 402a and 402b (also referred to as wafer supports, support extensions, or support grips). In one embodiment, retractable support extensions 402a and 402b are pivotably mounted to an underside of corresponding arms of end effector 100. In one exemplary embodiment, actuators 400 may drive dials 401a and 404b through mating gears to turn or pivot support extensions 402a and 402b, respectively, around an axis. The support extensions 402a and 402b will clear the wafer plane when in a retracted position as illustrated in FIG. 6. It should be noted that alternative actuator means may be provided to retract support extensions 402a and 402b and the embodiments are not limited to the actuators and mating gears. For example, support extensions 402a and 402b may drop down vertically rather than turn. Known mechanical means through levers, pulleys, etc., can provide the structure to retract, rotate, or release the support extensions. It should be appreciated that the retractable support extensions enable vertical shifting of end effector 100 with minimal R motion to minimize the area required for scanning up and down for positioning. It should be appreciated that while components of the end effector described herein is referred to as separate components, the end effector may be a monolithic block having the components. However, the end effector may be also constructed from separate components or a combination of component blocks and separate components in other embodiments.

It should be appreciated that the above-described end effector, substrate container, substrate chuck and system are not limited to the exemplary embodiments described herein. It should also be appreciated that various modifications, adaptations, and alternative embodiments thereof may be made within the scope and spirit of the present invention. For example, the container and system may also be used to store other types of substrates or be used in connection with other equipment within a semiconductor manufacturing facility. It should be appreciated that many of the inventive concepts described above would be equally applicable to the use of non-semiconductor manufacturing applications as well as semiconductor related manufacturing applications. Exemplary uses of the inventive concepts may be integrated into solar cell manufacturing and related manufacturing technologies, such as; single crystal silicon, polycrystalline silicon, thin film, and organic processes, etc.

Any of the operations described herein that form part of the invention are useful machine operations. The invention also relates to a device or an apparatus for performing these operations. The apparatus can be specially constructed for the required purpose, or the apparatus can be a general-purpose computer selectively activated, implemented, or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

1. An end effector, comprising:
a first arm extending from an end effector support body, and a second arm extending from the end effector support body, the first arm and the second arm each having a corresponding support extension for supporting a peripheral region of a substrate, wherein the second arm and the first arm include sensors integrated thereon, the sensors located at a distal end of the first and the second arms past the corresponding support extension.

2. The end effector of claim 1, wherein the first and second arms are affixed to the end effector support body through a rotation mechanism enabling adjustment of a planar orientation of the end effector support body.

3. The end effector of claim 2, wherein the support extensions are pivotably affixed to the corresponding arms.

4. The end effector of claim 1, wherein the sensors are positioned to detect a plane different than a plane of travel of the substrate.

5. The end effector of claim 1, further comprising:
a third arm extending from the end effector support body, the third arm configured to slidably extend away from the end effector support body, wherein a distal end of the third arm includes a sensor.

6. The end effector of claim 5, wherein a line of sensing for the sensors on the first and second arms is orthogonal to a line of sensing for the sensor on the third arm.

7. The end effector of claim 1, wherein the end effector support body is rotatable to adjust to any deflection of the substrate detected by the sensors.

8. The end effector of claim 1, wherein the support extensions include support pads for supporting an underside of the substrate, the support pads having support pad sensors embedded therein, the support pad sensors are configured to sense one of conductivity, weight, capacitance, or vacuum level.

9. A system for transporting a substrate, comprising;
a substrate container having a support structure disposed within a housing assembly, the support structure having a plurality of support extensions extending into an inner region of the housing assembly, the plurality of support extensions arranged as horizontally coplanar pairs, wherein support extensions of different horizontal planes are vertically aligned;
an end effector adapted to support a peripheral region of the substrate outside of the horizontally coplanar pairs of a surface of a substrate housed within the substrate container, the end effector having a first arm extending from an end effector support body, and a second arm extending from the end effector support body, the first arm and the second arm each having a corresponding substrate support extensions for supporting a peripheral region of the substrate, wherein the second arm and the first arm include sensors integrated thereon; and
a computing device in communication with sensors, the computing device receiving signals from the sensors.

10. The system of claim 9, wherein an amount of tilting for a plane connecting the first and the second arm is controlled by the computing device based on the signals.

11. The system of claim 9, wherein the support extensions of the first and the second arms are pivotably mounted.

12. The system of claim 11, further comprising:
a drive mechanism associated with each of the arms, the drive mechanism driving the pivotably mounted support extensions.

13. The system of claim 12, wherein the support extensions are mounted to a bottom surface of corresponding arms.

14. The system of claim 11, wherein the support extensions of the first and the second arms include support pads for supporting an underside of the substrate, the support pads having support pad sensors incorporated therein, the support pad sensors in communication with the computing device.

15. The system of claim 14, wherein the support pad sensors are configured to detect acquiring the substrate.

16. The system of claim 14, wherein the support pad sensors are configured to sense one of conductivity, weight, capacitance, or vacuum level.

17. The system of claim 9, wherein the sensors are located at a distal end of the first and the second arms past the corresponding support extensions such that the sensors are external to each of the plurality of container support extensions.

18. The system of claim 9 wherein the end effector support body is rotatable.

19. The system of claim 9, wherein the sensors are configured to detect whether the support extensions are within a plane of travel of the first and the second arms.

20. The system of claim 9, wherein the computing device adjusts a position of the end effector based on the signals from the sensors.

21. An end effector, comprising:
a first arm extending from an end effector support body, and a second arm extending from the end effector support body, the first arm and the second arm each having a corresponding support extension for supporting a peripheral region of a substrate, wherein the second arm and the first arm include sensors integrated thereon, the sensors located at a proximate end of the first and the second arms prior to the corresponding support extension.

22. The end effector of claim 21, wherein the first and second arms are affixed to the end effector support body through a rotation mechanism enabling adjustment of a planar orientation of the end effector support body.

23. The end effector of claim 22, wherein the support extensions are pivotably affixed to the corresponding arms.

24. The end effector of claim 21, wherein the sensors are positioned to detect a plane different than a plane of travel of the substrate.

25. The end effector of claim 21, further comprising:
a third arm extending from the end effector support body, the third arm configured to slidably extend away from the end effector support body, wherein a distal end of the third arm includes a sensor.

26. The end effector of claim 25, wherein a line of sensing for the sensors on the first and second arms is orthogonal to a line of sensing for the sensor on the third arm.

27. The end effector of claim 21, wherein the support extensions include support pads for supporting an underside of the substrate, the support pads having support pad sensors embedded therein, the support pad sensors are configured to sense one of conductivity, weight, capacitance, or vacuum level.
